(19) United States
(12) Patent Application Publication
(10) Pub. No.: US 2014/0026942 A1
(43) Pub. Date: Jan. 30, 2014

(54) SOLAR PANEL WITH INTERNAL TRACKING

(71) Applicant: Jason LEE, San Jose, CA (US)

(72) Inventor: Jason LEE, San Jose, CA (US)

(21) Appl. No.: 13/952,523

(22) Filed: Jul. 26, 2013

Related U.S. Application Data
(60) Provisional application No. 61/677,389, filed on Jul. 30, 2012.
(60) Provisional application No. 61/705,933, filed on Sep. 26, 2012.

(51) Int. Cl. H01L 31/052

(52) U.S. Cl. CPC H01L 31/0525
USPC 136/246

(57) ABSTRACT

A self-tracking solar panel is presented that includes internal tracking. A self-tracking solar panel can include an array of active materials fixed to an underside of a top cover or to a bottom panel of the solar panel and an array of tracking solar collectors that concentrate solar energy onto the array of active materials, the array of tracking solar collectors moving in relation to the array of active materials.

### CROSS REFERENCE TO RELATED APPLICATIONS

This U.S. patent application is based on and claims the benefit of priority under 35 U.S.C.§119 from provisional U.S. Patent Application Ser. No. 61/677,389, filed on Jul. 30, 2012, and provisional U.S. Patent Application Ser. No. 61/705,933, filed on Sep. 26, 2012. Both applications are hereby incorporated by reference in their entirety for all purposes.

### TECHNICAL FIELD

Embodiments of the present invention are related to solar concentrators for solar power generation.

### DISCUSSION OF RELATED ART

Solar panels can be utilized either individually or as parts of a larger system. In some systems, solar panels are constructed with a glass covering over an active photo-voltaic material. Solar energy passing through the glass covering is incident on the active material and solar power is generated. In some cases, individual solar panels can be mounted on tracking systems that arrange for the solar panel to track the position of the sun in order to optimize the collection of solar energy. Such tracking systems are often cumbersome and expensive to install and maintain. Further, in some systems solar concentrators can be utilized to save the cost of active material. However, such solar concentrator systems can have the same problems with their tracking systems as the tracking systems employed with solar panels.

Therefore, there is a need for more efficient self tracking solar panels.

### SUMMARY

In accordance with aspects of the present invention, a solar panel includes an array of active materials fixed to an underside of a top cover or to a bottom panel of the solar panel; and an array of tracking solar collectors that concentrate solar energy onto the array of active materials, the array of tracking solar collectors moving in relation to the array of active materials.

These and other embodiments are further discussed below with respect to the following figures.

### BRIEF DESCRIPTION OF THE DRAWINGS

FIGS. 1A, 1B, and 1C illustrate embodiments of a self tracking solar panel according to the present invention.

FIG. 2 illustrates a cooling system for solar panels according to some embodiments of the present invention.

FIG. 3 illustrates another embodiment of a self tracking solar panel according to the present invention.

FIG. 4 illustrates aspects of the embodiment of tracking solar panel illustrated in FIG. 3.

FIG. 5 illustrates aspects of the embodiment of tracking solar panel illustrated in FIG. 3.

FIG. 6 illustrates another embodiment of a self tracking solar panel according to the present invention.

### DETAILED DESCRIPTION

In some embodiments of the present invention, a self-tracking solar panel that includes a built-in tracking mechanism is presented. These embodiments do not utilize bulky external tracking systems. However, some embodiment of self-tracking solar panels according to the present invention can have the same form factor as conventional solar panels while utilizing much less active material.

In the following description, specific details are set forth describing some embodiments of the present invention. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

Further, this description's terminology is not intended to limit the scope of the invention. For example, spatially relative terms—such as “beneath”, “below”, “lower”, “above”, “upper”, “proximal”, “distal”, “horizontal”, “vertical” and the like—may be used to describe one element's or feature's relationship to another element or feature as illustrated in the figures. These spatially relative terms are intended to encompass different positions and orientations of the device in use or operation in addition to the position and orientation shown in the figures. For example, if the device in the figures is turned over, elements described as “below” or “beneath” other elements or features would then be “above” or “over” the other elements or features. Thus, the exemplary term “below” can encompass both positions and orientations of above and below. The device may be otherwise oriented (rotated 90 degrees or at other orientations), and the spatially relative descriptors used herein interpreted accordingly Likewise, descriptions of movement along and around various axes include various special device positions and orientations. In addition, the singular forms “a”, “an”, and “the” are intended to include the plural forms as well, unless the context indicates otherwise. And, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electrically or mechanically directly coupled, or they may be indirectly coupled via one or more intermediate components.

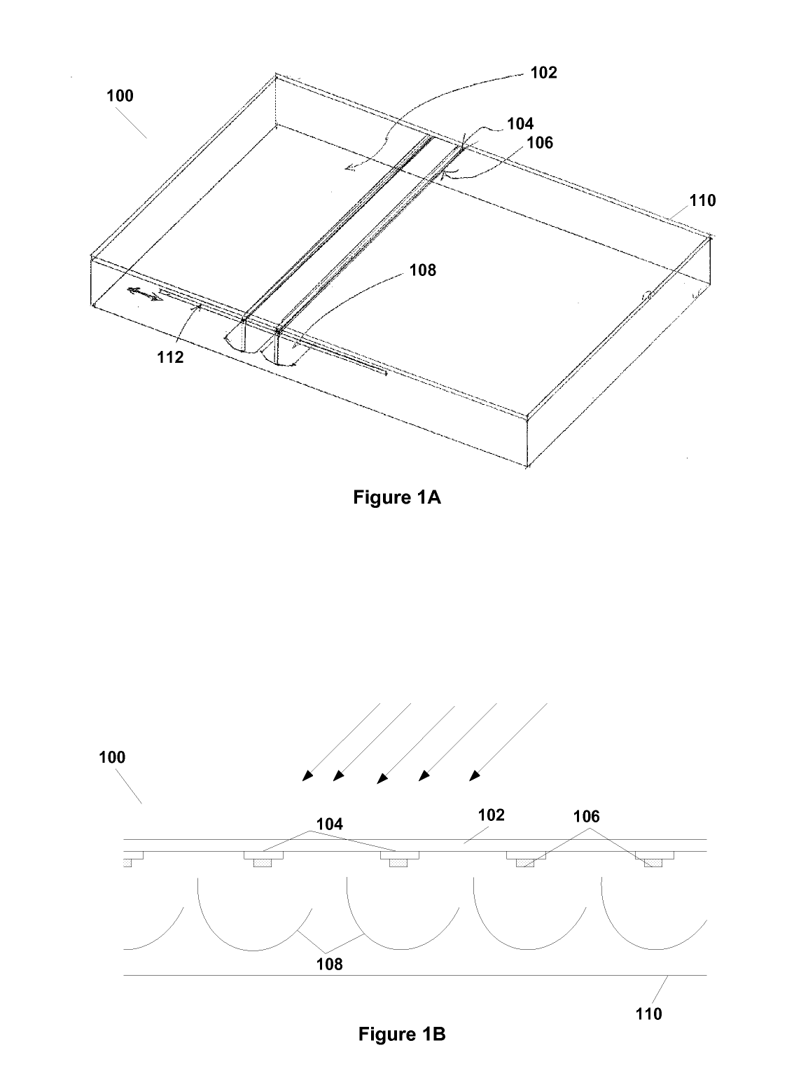

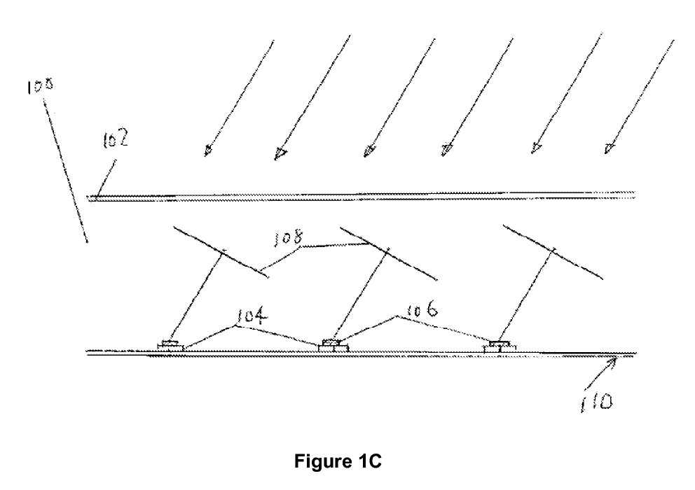

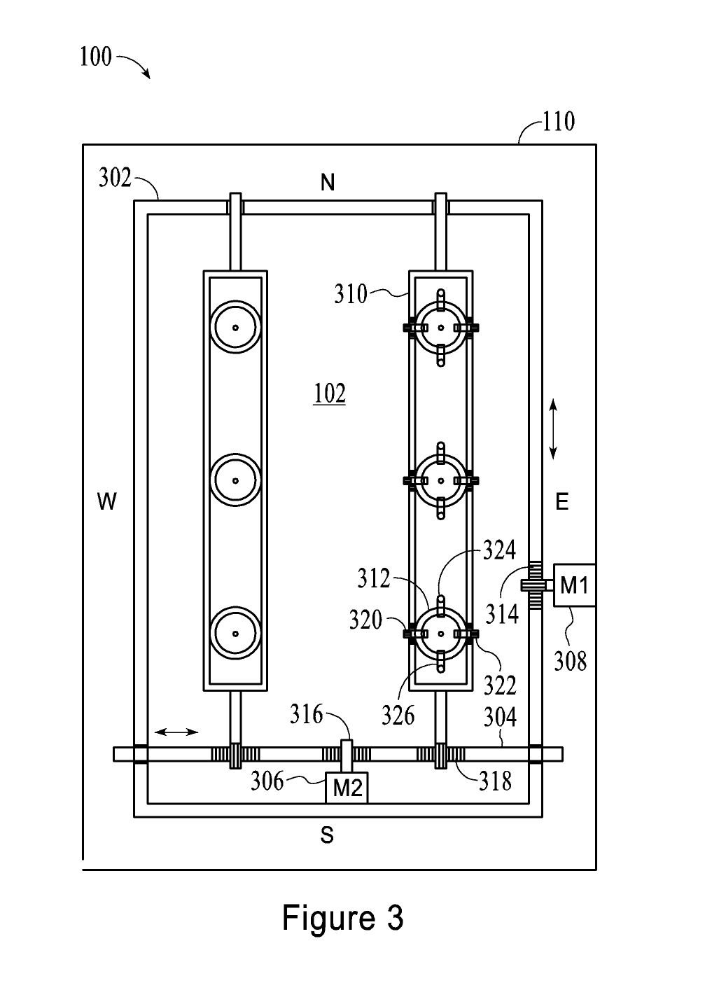

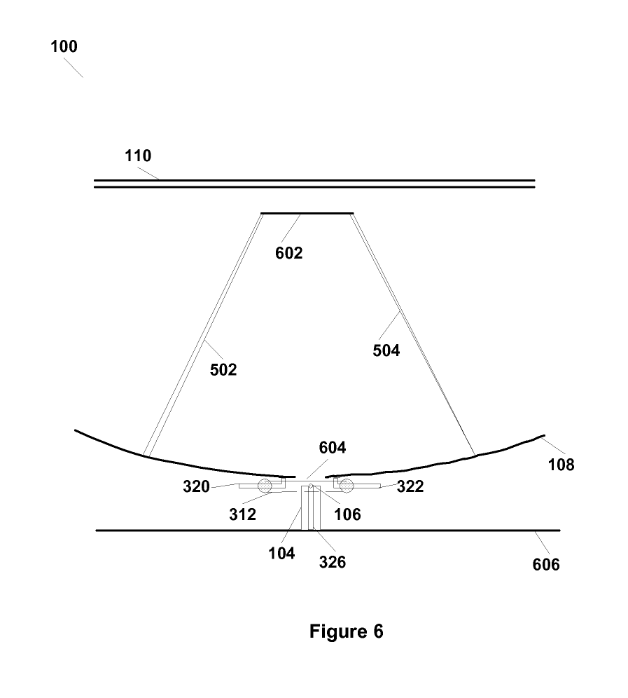

FIGS. 1A and 1B illustrate a self-tracking solar panel 100 according to some embodiments of the present invention. The embodiment of solar panel 100 illustrated in FIGS. 1A and 1B is a single-axis tracking solar panel. A dual-axis self-tracking solar panel 100 is illustrated in FIGS. 3, 4, and 5. An inverted dual-axis self-tracking solar panel 100 is illustrated in FIG. 6. In each example, solar panel 100 includes built-in tracking to follow the sun and to concentrate solar energy onto photovoltaic active materials 106.

As shown in FIGS. 1A and 1B, solar panel 100 can includes a panel frame with a top glass cover 102 that is mounted in a rigid frame 110. An array of linearly arranged substrates 104, each with a solar active material 106, is mounted in parallel strips below glass cover 102. Mounted below glass cover 102 is a corresponding array of solar collectors 108, which can be shaped as a parabolic trough to reflect sunlight onto solar active material 106. As such, the array of solar collectors 108 illustrated in FIGS. 1A and 1B can be an array of parabolic troughs. As shown in FIGS. 1A and 1B, solar active material 106 is formed in a long strip along the bottom of top glass cover 102 and solar collector 108 is positioned to rotate relative to active material 106 and focus sunlight onto active material 106.

In the example shown in FIG. 1A, a linear gear 112 is mechanically coupled to rotate solar collector 108. Linear gear 112 can be operated by a driving motor in such a way that solar collector 108 tracks the position of the sun in order to optimally focus sunlight onto active material 106. As is illustrated in FIG. 1B, linear gear 112 drives each of solar collectors 108 to focus solar energy on active material 106. Although a linear gear is illustrated in these embodiments, other drive mechanisms (for example, a belt drive, chain drive, gear train, slew drive, or other mechanical coupling) can be utilized to rotate each of solar collectors 108.

As shown in FIGS. 1A and 1B, active material 106 can be any photovoltaic material. Solar collectors 108 can be any reflective surface in any shape that focuses light incident on solar collectors 108 onto active material 106. In some embodiments, solar collectors 108 can form a parabolic reflective trough-shaped minor array.

In some embodiments, solar panel 100 can be a standard sized solar panel. Linear gear 112 and solar collector 108 provides a one-axis tracking array to follow the sun and concentrate solar power onto active material 106. In some embodiments, solar panel 100 can be handled similarly to other solar panels and can be mounted in any position relative to the sun such that the array of solar collectors 108 can track and capture sunlight for long periods throughout the day.

In some embodiments, sensors and motors can be inside frame 110 and can drive the position of solar collectors 108. In some embodiments, sensors and motors can be external to solar panel 100 and may drive multiple ones of panels 100. In each panel, each of solar collectors 108 are coupled so that they move together.

Both the array of active material 106 and the array of solar collectors 108 are enclosed in frame 110 and sealed with top cover 102, which protects them from the environmental hazards of wind, rain, and snow. The mechanical design of solar collectors 108, linear gear 112, and drivers can be made as light as possible. There is no need of bulky structural elements that are commonly utilized in conventional tracking systems.

Further, as shown in FIGS. 1A and 1B, movement of passive materials such as solar collectors 108 and active material 106 are detached from each other. Active material 106 is stationary with respect to top cover 102 and frame 110 while solar collector 108, which can be parabolic trough-shaped mirrors, swing around the focus line on active material 106 while following the sun.

As a result of active material 106 being fixed on cover 102, waste heat can be dissipated by conduction through cover 102 and convection to air. Having an uninterrupted heat path can be important to the thermal design of some embodiments of panel 100.

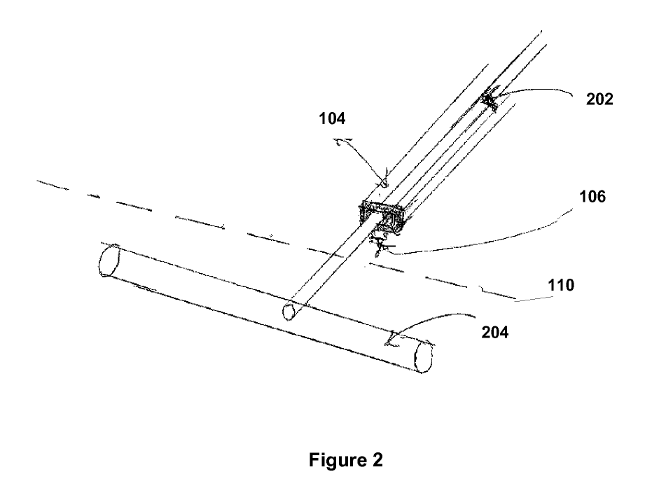

FIG. 2 illustrates an active cooling system for solar panel 100 according to some embodiments of the present invention. In some embodiments, top cover 102 should not utilize an infra-red reflective coating in order to include infra-red heat as part of the thermal energy recovered. The heat can be recovered in a roof-top or backyard setting, for example by heating water, and can be important in significantly increasing the overall system efficiency.

FIG. 1C illustrates an embodiment where solar collectors 108 are lenses instead of mirrors. In this case substrates 104 and active materials 106 are located on frame 110 instead of on top cover 102. However, all other features remain as described in FIGS. 1A and 1B. In the embodiment shown in FIG. 1C, solar collectors 108 can be a Fresnel lens, a non-imaging Fresnel lens, or any other lens system that concentrates solar energy onto active materials 106.

FIGS. 1A, 1B, and 1C can include active tracking systems that allow solar collectors 108 to concentrate solar energy onto active materials 106. Utilization of solar collectors 108 can help to save the cost of active materials. In some embodiments, embodiments of the present invention may not include a tracking system. Instead, solar collectors 108 may be adjusted and fixed in place to provide solar power to active materials 106.

As shown in FIG. 2, a cooling tube 202 can be thermally coupled, or provided through, substrate 104 and coupled to a manifold 204. Manifold 204 can be positioned outside of frame 110, but may be attached to frame 110. In this case, cooling fluid may be passed through cooling tube 202 and manifold 204. Both cooling tube 202 and manifold 204 are fixed relative to top cover 102 and therefore are stationary with respect to solar collectors 108. Further, since cooling tube 202 is stationary with respect to manifold 204, there is no leakage at joints or failures caused by the motion of tube 202 with respect to manifold 204. Heated fluid flowing through cooling tube 202 can, for example, be hot water that can be utilized for domestic purposes. Other cooling systems that may help distribute heat, such as for example conducting fingers, heat pipe, or heat spreader, can be utilized as well.

Active material 106 can be any optically active material that is commonly utilized for photovoltaic collection of solar energy. Such materials may include, for example, single crystal silicon, GaAs, or other materials. In some embodiments, active material 106 can include optics that transmit light to an active material that is located elsewhere. Substrate 104 can be formed of any substrate material. Top cover 102 can be glass, for example tempered glass. Top cover 102 can be thinner than in conventional panels since it does not need to protect the full area of solar panel 100, needing only to protect the much smaller area of active material 106. In some embodiments, plastic or other materials can be utilized to further reduce weight.

The embodiments illustrated in FIGS. 1A, 1B, and 2 illustrate a single-axis drive mechanism. Solar panel 100, similar to conventional solar panels, can be mounted in any orientation. Solar collectors 108 rotate to track the sun and focus the maximum amount of solar power on strips of active material 106. In some embodiments, a single-axis solar panel 100 can be mounted on a separate single-axis tracking system, similar to conventional solar panels. Although some embodiment of single-axis solar panel 100 may not generate as much power as conventional panels, application of single-axis solar panel 100 in a solar farm may produce at least as much power overall because there is no loss due to spacing, and the system does not need to move then entire solar panel on a tracking mechanism.

FIG. 3 illustrates another embodiment of solar panel 100. Solar panel 100 as illustrated in FIG. 3 is a dual-axis solar panel. As shown in FIG. 3, a first motor 308 is fixed on frame 110 and mechanically coupled to a tracking frame 302 at linear gear 314. As is shown, tracking frame 302 moves in a north/south direction responsive to motor 308. Further, motor 306 is mounted on tracking frame 302 and mechanically coupled to a second tracking frame 304 at linear gear 316. As illustrated in FIG. 3, second tracking frame 304 moves in an east/west direction in response to motor 306. Second tracking frame 304 is coupled to a third yoke-shaped tracking frame 310 at linear gear 318. Therefore, as second tracking frame 304 is moving in an east/west direction, third tracking frame 310 is rotating around a north/south axis.

As is further illustrated in FIG. 3, a flex ring 312 is coupled to third tracking frame 310 and to the underside of top plate 102. As such, flex ring 312 has L-shaped pins 324 and 326 that are rotatably fixed to top plate 102 to allow for rotation around the north/south axis. Further, flex ring 312 includes gear pins 320 and 322 that pass through flex ring 312 and are coupled to linear gears on tracking frame 310. Therefore, as tracking frame 310 is rotated around the north/south axis, flex ring 312 rotates around the north-south axis. Further as tracking frame 310 is moving in a north/south direction as a result of tracking frame 302 moving in a north-south direction, gear pins 320 and 322 are rotated around an east/west axis.

Directions north, south, east, and west are provided for descriptive purposes only and designation of those directions are not intended to be limiting. Although panel 100 may be mounted in the orientation illustrated in FIG. 3, in some applications panel 100 may be rotated in any way with respect to these geographic designations. The designation north, south, east, and west provided in this description is for convenience only.

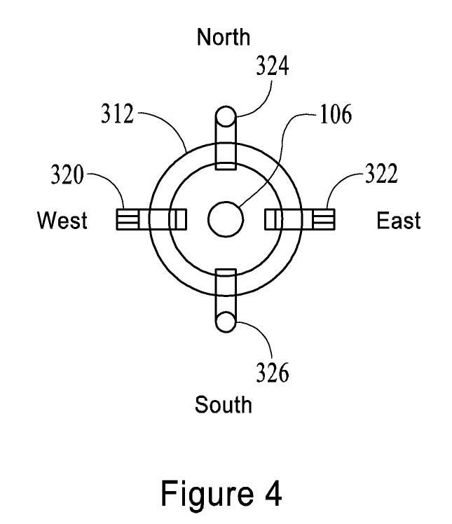

FIG. 4 further illustrates the motion of flex ring 312. As shown in FIG. 4, L-shaped pins 324 and 326 are coupled through flex ring 312 to allow flex ring 312 to rotate around a north/south axis. Gear pins 320 and 322 are coupled through flex ring 312 to allow gear pins 320 and 322 to rotate around an east/west axis. Additionally, active material 106, instead of being a strip of material as illustrated in FIGS. 1A and 1B, is a smaller area material that is positioned at the center of flex ring 312. Further, pins 324 and 326 are positioned to allow flex ring and active material 106 to be positioned in the center of flex ring 312.

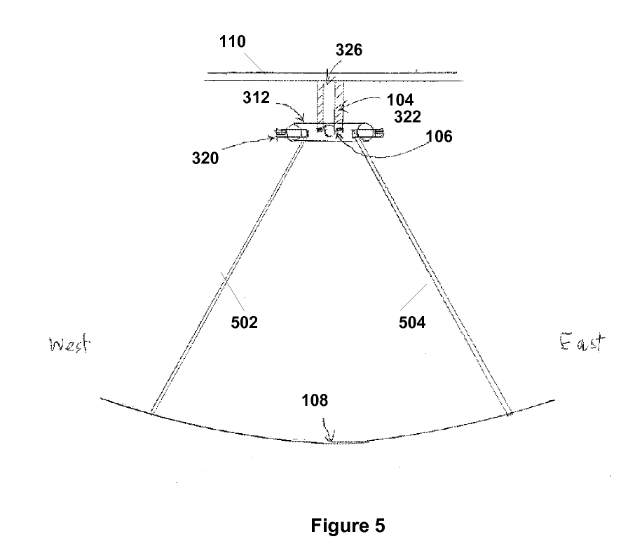

FIG. 5 illustrates a side view of one concentrator module of panel 100 as shown in FIG. 3. As shown in FIG. 5, L-shaped pin 326 is suspended from top cover 110. Flex ring 312 is rotatably coupled to L-shaped pin 326 so that flex ring 312 rotates around L-shaped pin 326 around a north/south axis. Gear pins 320 and 322, which rotated around an east/west axis, pass through flex ring 312 and are coupled to struts 502 and 504, respectively. As is illustrated in FIG. 5, struts 502 and 504 are mechanically coupled to solar collector 108. Solar collector 108 can be any reflector that concentrates solar energy that passes through top cover 110 onto active material 106, for example a two-dimensional parabolic reflector.

As illustrated in FIGS. 3, 4, and 5, solar collector 108 can be rotated in both the east/west direction and in the north/south direction in order to track the sun by appropriately driving motors 306 and 308. The embodiment of solar panel 100 illustrated in FIG. 3 includes a two dimensional array of coupled solar collectors 108, each focusing collected solar energy onto a small active material 106. As shown in FIG. 4, the surface area of active material 106 should be large enough to receive the solar energy from solar collectors 108. Although shown as a circular area in FIG. 4, active material 106 can be of any shape that spans an area where solar energy will be concentrated. Similar mechanisms as discussed with FIG. 2 can be utilized to cool active material 106.

Solar panel 100 can be fixedly mounted, for example on a roof-top or ground arrangement. Solar panel 100 is mounted such that the internal tracking mechanism can follow the sun. A dual-axis tracking solar panel can be mounted in any orientation.

Individual components of solar panel 100 are enclosed within the panel frame formed of frame 110 and covering top glass 102 and therefore avoid degradation due to environmental hazards such as wind, rain and snow. Consequently, mechanical design of solar panel 100 can be much lighter than that utilized in more conventional tracking systems. In panel 100, active material 106 is fixed to top glass 102, which is fixedly mounted, and solar collectors 108 are rotated relative to active material 106 in order to concentrate solar energy onto active material 106. Some examples of rotating solar collectors 108 are disclosed here. However one skilled in the art can provide other methods of rotating solar collectors 108. For example, all of the modules can be linked together and only one driven by motors 306 and 308.

FIG. 6 illustrates another embodiment of solar panel 100. As shown in FIG. 6, active material 106 and substrate 104 may be fixedly mounted to panel frame on a bottom panel 606. The drive mechanism can be the same as that described with FIG. 3, except that flex ring 312 is attached to the reflector portion of solar collector 108. Further, solar collector 108 includes an opening 604 through which solar energy is incident on active material 106. Struts 502 and 504, which are connected to the reflection portion of solar collector 108, are utilized to support a secondary minor 602. Solar radiation transmitted through top cover 110 is focused by the reflective portion of solar collector 108 and secondary mirror 602 onto active material 106 through opening 604. As described with FIG. 3, solar collector 108 can be moved to track the sun. As before, active material 106 is fixed to bottom panel 606 while solar collector 108 is rotated around active material 106. Thermal energy from active material 106 and substrate 104 can be coupled into bottom panel 606 and either actively (e.g. with cooling tubes) or passively (e.g. through thermal conduction) removed from active material 106. A single-axis embodiment can be similarly constructed where, again, active material 106 is a strip of active material.

The above detailed description is provided to illustrate specific embodiments of the present invention and is not intended to be limiting. Numerous variations and modifications within the scope of the present invention are possible. The present invention is set forth in the following claims.

What is claimed is:

1. A solar panel, comprising:
a panel frame;
an array of active materials fixed within the panel frame; and
an array of tracking solar collectors that concentrate solar energy onto the array of active materials, the array of tracking solar collectors being mounted within the panel frame and configured to move in relation to the array of active materials.

2. The solar panel of claim 1, wherein the panel frame comprises a top glass cover that is mounted within a rigid frame.

3. The solar panel of claim 2, wherein the array of active materials comprises strips of active materials arranged in parallel and mounted to the top glass cover.

4. The solar panel of claim 3, wherein the array of tracking solar collectors is an array of parabolic troughs aligned with the strips of active materials and is configured to rotate with respect to the active materials to concentrate solar energy on the active materials.

5. The solar panel of claim 4, wherein the array of parabolic troughs is driven by a motor coupled to rotate the array of parabolic troughs.
